(19) United States
(12) Patent Application Publication
(10) Pub. No.: US 2019/0280119 A1
(43) Pub. Date: Sep. 12, 2019

(54) SUPER JUNCTION POWER TRANSISTOR AND PREPARATION METHOD THEREOF

(71) Applicant: SUZHOU ORIENTAL SEMICONDUCTOR CO., LTD, Jiangsu (CN)

(72) Inventors: Lei LIU, Jiangsu (CN); Wei LIU, Jiangsu (CN); Yuanlin YUAN, Jiangsu (CN); Yi GONG, Jiangsu (CN)

(73) Assignee: SUZHOU ORIENTAL SEMICONDUCTOR CO., LTD, Jiangsu (CN)

(21) Appl. No.: 16/304,827

(22) PCT Filed: Dec. 27, 2017
(86) PCT No.: PCT/CN2017/118965

§ 371 Date: Nov. 27, 2018

(30) Foreign Application Priority Data
Dec. 28, 2016 (CN) 201611236171.X

(51) Int. Cl. H01L 29/78; H01L 29/423; H01L 29/06; H01L 29/66

(52) U.S. Cl. CPC H01L 29/7813; H01L 29/4236; H01L 29/66734; H01L 29/0634; H01L 29/7831; H01L 29/4238

(57) ABSTRACT

Provided are a super junction power transistor and a preparation method thereof. The super junction power transistor includes a first substrate epitaxial layer of a first doping type and a second substrate epitaxial layer of the first doping type disposed on the first substrate epitaxial layer, a drain region of the first doping type and multiple columnar epitaxial doping regions of the second doping type are formed in the first substrate epitaxial layer, and multiple trenches are disposed in the second substrate epitaxial layer, and a composite gate structures is formed in each of the multiple trenches, a body region of the second doping type is disposed in the second substrate epitaxial layer between adjacent trenches, and a source region of the first doping type is disposed in the body region.

### CROSS REFERENCE TO RELATED APPLICATIONS

This is a National Stage Application, filed under 35 U.S.C. 371, of International Patent Application No. PCT/CN2017/118965, filed on Dec. 27, 2017, which claims priority to Chinese patent application No. 201611236171.X filed on Dec. 27, 2016, contents of both of which are incorporated herein by reference in their entireties.

### TECHNICAL FIELD

The present disclosure relates to a technical field of semiconductor power devices, for example, to a super junction power transistor and a preparation method thereof.

### BACKGROUND

The super junction power transistor is provided with multiple columnar epitaxial doping regions in a substrate epitaxial layer. Each of the multiple columnar epitaxial doping regions has an opposite doping type to the substrate epitaxial layer. Charge carriers between each of the multiple columnar epitaxial doping regions and the substrate epitaxial layer are easy to deplete to increase a breakdown voltage of the super junction power transistor. In a related art, a preparation method of the super junction power device is firstly provided the substrate epitaxial layer with multiple trenches, then substrate epitaxial layer materials are grown to form the multiple columnar epitaxial doping regions in the multiple trenches, then a body region is formed on the top of each of the multiple columnar epitaxial doping regions and a source region is formed in the body region. The defect of the related art is if an on resistance of the super junction power transistor remains unchanged, the breakdown voltage of the super junction power transistor cannot be continuously increased, also, if the breakdown voltage of the super junction power transistor is increased by increasing the thickness of the substrate epitaxial layer, the on resistance of the super junction power transistor is increased.

### SUMMARY

The present disclosure provides a super junction power transistor and a preparation method thereof. A double-layer substrate epitaxial layer structure is provided, a super junction structure is formed in a first substrate epitaxial layer, and a composite gate structure is formed in a second substrate epitaxial layer, thereby addressing the technical problem in the related art that the super junction power transistor cannot increase the breakdown voltage and decrease the on resistance simultaneously.

A super junction power transistor includes a first substrate epitaxial layer of a first doping type and a second substrate epitaxial layer of the first doping type disposed on the first substrate epitaxial layer. A drain region of the first doping type and multiple columnar epitaxial doping regions of the second doping type are formed in the first substrate epitaxial layer. Multiple trenches are disposed in the second substrate epitaxial layer and a composite gate structure is formed in each of the multiple trenches. A body region of the second doping type is disposed in the second substrate epitaxial layer between adjacent trenches, and a source region of the first doping type is disposed in the body region.

The number of the composite gate structures in the second substrate epitaxial layer is greater than that of the columnar epitaxial doping regions in the first substrate epitaxial layer.

The composite gate structures are sequentially disposed on the multiple columnar epitaxial doping regions and the first substrate epitaxial layer between adjacent columnar epitaxial doping regions.

A doping concentration of the second substrate epitaxial layer is greater than that of the first substrate epitaxial layer.

Each of the multiple trenches includes a first trench and a second trench with an opening is disposed at the bottom of the first trench. Each of the composite gate structures includes a gate, a gate oxide layer, a split gate and a field oxide layer. The gate oxide layer is disposed on an inner surface of the first trench. The gate is disposed on each of opposite side walls of the first trench and the gate oxide layer is covered by the gate. The field oxide layer is disposed on opposite surfaces of the gate and an inner surface of the second trench. The split gate is disposed in an accommodation space enclosed by the field oxide layer.

A width of the first trench is greater than that of the second trench.

The split gate is connected to the source region through a conductive layer.

The first doping type is a P-type doping, and the second doping type is an N-type doping; or the first doping type is the N-type doping, and the second doping type is the P-type doping.

A super junction power transistor preparation method includes:

forming a plurality of columnar epitaxial doping regions in the first substrate epitaxial layer;

forming a second substrate epitaxial layer on the first substrate epitaxial layer;

forming a hard mask layer is formed on the second substrate epitaxial layer, and the hard mask layer is etched to form an opening of the hard mask layer;

etching the second substrate epitaxial layer to form multiple first trenches in the second substrate epitaxial layer;

forming a gate oxide layer on the inner surface of the first trench;

forming a gate on each of opposite side walls of the first trench;

etching the exposed gate oxide layer and etching the second substrate epitaxial layer to form the second trench;

covering inner surface of the second trench and opposite surfaces of the gate to form the field oxide layer, and the spilt gate is formed in the accommodation space enclosed by the field oxide layer;

forming a body region in the second substrate epitaxial layer, and forming a source region in the body region;

and forming a drain region at a bottom of the first substrate epitaxial layer.

When forming the first trench, a horizontal etching is increased so that the width of of each of formed first trenches is greater than a width of a respective opening of the hard mask layer.

The number of the first trenches in the second substrate epitaxial layer is greater than that of the columnar epitaxial doping regions in the first substrate epitaxial layer.

The doping type of the second substrate epitaxial layer and the first substrate epitaxial layer are the same, and the doping concentration of the second substrate epitaxial layer is greater than that of the first substrate epitaxial layer.

The super junction power transistor and the preparation method thereof provided by the present disclosure adopts the double-layer substrate epitaxial layer structure. The columnar epitaxial doping regions are formed in the first substrate epitaxial layer and the composite gate structures which has a greater number than the columnar epitaxial doping regions may be formed in the second substrate epitaxial layer, which may form more current channels and the on resistance of the super junction power transistor is reduced. Meanwhile, the doping concentration of the second substrate epitaxial layer is configured to be greater than that of the first substrate epitaxial layer, which can increase the breakdown voltage of the super junction power transistor. In addition, by disposing a trench structure in the second substrate epitaxial layer and achieving the gate and the spilt gate through self-alignment, an overlapping area between the gate and a drain is decreased, a capacitance between the gate and the drain is reduced and the switching speed of the super junction power transistor is increased.

### BRIEF DESCRIPTION OF DRAWINGS

FIG. 1 is a sectional view of structures of a super junction power transistor according to an embodiment;

FIG. 2 is a flowchart of a super junction power transistor preparation method according to an embodiment;

FIG. 3 is a flowchart of a super junction power transistor preparation method according to another embodiment;

FIG. 4 is a structural diagram shown in step 10 of a super junction power transistor preparation method according to an embodiment;

FIG. 5 is a structural diagram shown in step 2001 of a super junction power transistor preparation method according to an embodiment;

FIG. 6 is a structural diagram shown in step 2002 of a super junction power transistor preparation method according to an embodiment;

FIG. 7 is a structural diagram shown in step 2003 of a super junction power transistor preparation method according to an embodiment;

FIG. 8 is a structural diagram shown in step 2004 of a super junction power transistor preparation method according to an embodiment; and

FIG. 9 is a structural diagram shown in step 30 of a super junction power transistor preparation method according to an embodiment.

### DETAILED DESCRIPTION

The present disclosure will be described with reference to the drawings in the embodiments.

The terms used in the present disclosure such as “provided”, “comprising” and “including” do not exclude the presence or addition of one or more other components or other combinations. Meanwhile, to illustrate the embodiments of the present disclosure, diagrams in the drawings exaggerate a thickness of the layers and regions of the present disclosure, and the size of the listed diagrams does not represent the actual size. The accompanying drawings described herein are illustrative and not intend to limit the present disclosure. The listed embodiments in the Description are not intend to limit specific shapes of the regions shown in the drawings, but include obtained shapes, for example, deviations due to manufacturing, and curves obtained by an etching are usually characterized by bend or round, and only represented by rectangles in the embodiments.

A super junction power transistor includes a cell region and a terminal region. The cell region is used for obtaining a low on resistance, and the terminal region is used for increasing a withstand voltage of cells on the edge of the cell region. The terminal region is a universal structure in the super junction power transistor, and has different design structures based on different product requirements. Thus, the structure of the terminal region in the super junction power transistor will not be shown and illustrated in the embodiments. A structure of the super junction power transistor in the embodiments means a structure of the cell region in the super junction power transistor.

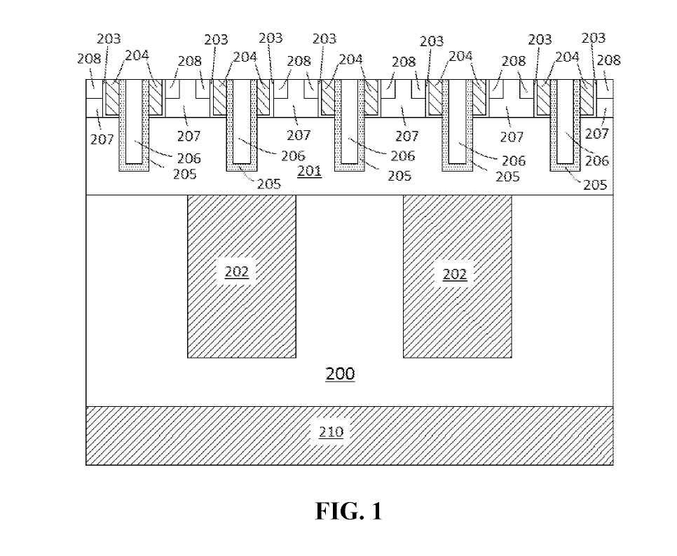

FIG. 1 is a sectional view of structures of a super junction power transistor according to the embodiment. As shown in FIG. 1, the super junction power transistor includes a first substrate epitaxial layer 200 of a first doping type and a second substrate epitaxial layer 201 of the first doping type. Multiple columnar epitaxial doping regions 202 of a second doping type forming a charge balance with impurities of the first substrate epitaxial layer 200 are disposed from the top of the first substrate epitaxial layer 200 to the inside of the first substrate epitaxial layer 200.

A material of the first substrate epitaxial layer 200 may be silicon.

The first doping type and the second doping type in this embodiment are opposite doping types. That is, if the first doping type is an N-type doping, and the second doping type is a P-type doping; and if the first doping type is the P-type doping, the second doping type is the N-type doping.

For the number of the columnar epitaxial doping regions 202 in the first substrate epitaxial layer 200, though the embodiment merely exemplarily illustrates two, the number of the columnar epitaxial doping regions 202 can be determined based on the product design requirements.

As shown in FIG. 1, the second substrate epitaxial layer 201 is disposed on the first substrate epitaxial layer 200. Multiple trenches are disposed from the top of the second substrate epitaxial layer 201 to the inside of the second substrate epitaxial layer 201, composite gate structures are formed the trenches, and the composite gate structure includes a gate 204, a gate oxide layer 203, a split gate 206 and a field oxide layer 205. In this embodiment, the trench includes an upper trench and a lower trench with an opening disposed at the bottom of the upper trench, the upper trench and the lower trench are disposed along a same direction. The gate oxide layer 203 is disposed on an inner surface of the upper trench, the gate 204 is disposed on each of opposite side walls of the upper trench and the gate oxide layer 203 is covered by the gate 204, the field oxide layer 205 is disposed on each of opposite surfaces of the gate 204 and an inner surface of the lower trench, the split gate 206 is disposed in a accommodation space enclosed by the field oxide layer 205.

In one embodiment, an upper surface of the split gate 206 is lower than an upper surface of the gate 204.

To optimize a gate structure and a manufacturing process of a device, a width of the upper trench may be greater than that of the lower trench.

A material of the second substrate epitaxial layer 201 and the material of the first substrate epitaxial layer 200 may be the same or different. In this embodiment, a doping concentration of the second substrate epitaxial layer 201 is greater than that of the first substrate epitaxial layer 200, thus a breakdown voltage of the device is increased.

For the composite gate structures in the second substrate epitaxial layer 201, in this embodiment, the number of the composite gate structures in the second substrate epitaxial layer 201 is greater than that of the columnar epitaxial doping regions 202 in the first substrate epitaxial layer 200, thus the number of current channels is increased and the on resistance of the device is reduced. For the position of the composite gate structures, the composite gate structures may be disposed on the columnar epitaxial doping regions 202 in the second substrate epitaxial layer 201 and the first substrate epitaxial layer 200 between adjacent two columnar epitaxial doping regions 202.

As shown in FIG. 1, the second substrate epitaxial layer 201 is further provided with a body region 207 of the second doping type disposed between adjacent trenches, and a source region 208 of the first doping type is disposed in the body region 207. In this embodiment, as shown in FIG. 1, the bottom of the body region 207 and the bottom of the upper trench are disposed at a same plane. That is, the gate oxide layer 203, the gate 204, the field oxide layer 205 and the split gate 206 simultaneously exist on the same plane. The lower trench is lower than the plane, the field oxide layer 205 and the split gate 206 simultaneously exist, without the gate oxide layer 203 and the gate 204 under the plane.

In this embodiment, as shown in FIG. 1, a drain region 210 of the first doping type is disposed at the bottom of the first substrate epitaxial layer 200.

The super junction power transistor further includes an insulating medium layer (not illustrated in the drawings) for electrical isolation, and a contact hole is disposed inside the insulating medium layer and filled with a metal layer to form ohmic contact, which is an universal structure in a related art, and will not be shown and illustrated in this embodiment.

In one embodiment, in this embodiment, the split gate 206 and the source region 208 are connected through the metal layer (that is, a conductive layer).

The super junction power transistor provided by the embodiment adopts the double-layer substrate epitaxial layer structure, the columnar epitaxial doping regions are formed in the first substrate epitaxial layer. The composite gate structures which have a greater number than the columnar epitaxial doping regions may be formed in the second substrate epitaxial layer. Thus more current channels may be formed and the on resistance of the super junction power transistor is reduced. Meanwhile, the doping concentration of the second substrate epitaxial layer is configured to be greater than that of the first substrate epitaxial layer, which can increase the breakdown voltage of the super junction power transistor. In addition, by disposing a trench structure in the second substrate epitaxial layer and achieving the gate and the spilt gate by self-alignment, an overlapping area between the gate and a drain is decreased, a capacitance between the gate and the drain is reduced and the switching speed of the super junction power transistor is increased.

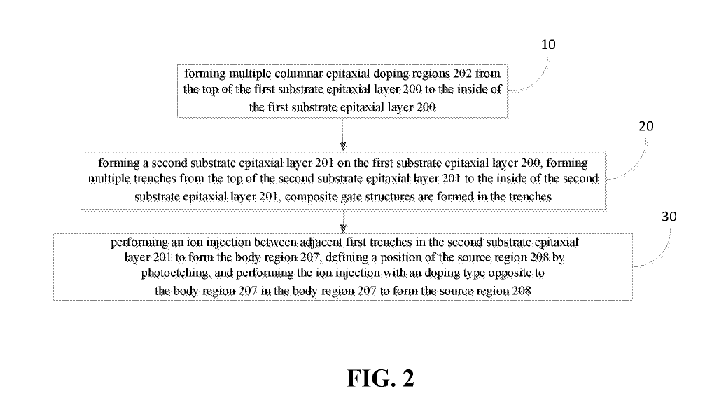

The embodiment further provides a super junction power transistor preparation method. As shown in FIG. 2, the method includes the steps described below.

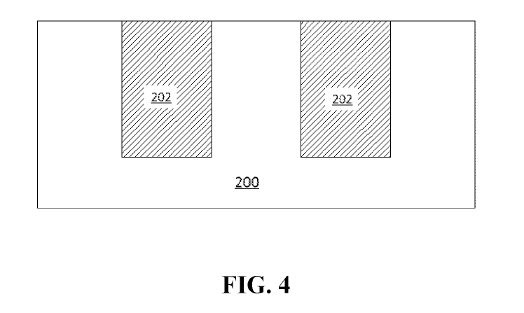

In step 10, as shown in FIG. 4, forming multiple columnar epitaxial doping regions 202 from the top of the first substrate epitaxial layer 200 to the inside of the first substrate epitaxial layer 200.

The above processing step includes: forming a hard mask layer on a surface of the first substrate epitaxial layer 200, the hard mask layer is usually a Oxide-Nitride-Oxide (ONO) structure, and includes a first oxide layer, a second nitride layer and a third oxide layer which are sequentially overlaid on the surface of the first substrate epitaxial layer 200. Then defining a trench position where the columnar epitaxial doping region 202 locates by photoetching, and the hard mask layer of the trench position is removed. The first substrate epitaxial layer 200 is etched by taking the remaining hard mask layer after the etching as an mask, thereby multiple trenches are formed in the first substrate epitaxial layer 200. Finally substrate epitaxial layer materials are grown in the trenches and a planarizing process is performed to form the columnar epitaxial doping region 202.

In this embodiment, the doping type of the first substrate epitaxial layer 200 is the first doping type and the doping type of the columnar epitaxial doping region 202 is the second doping type. The first doping type and the second doping type are opposite doping types. In one embodiment, the first doping type is an N-type, and the second doping type is a P-type.

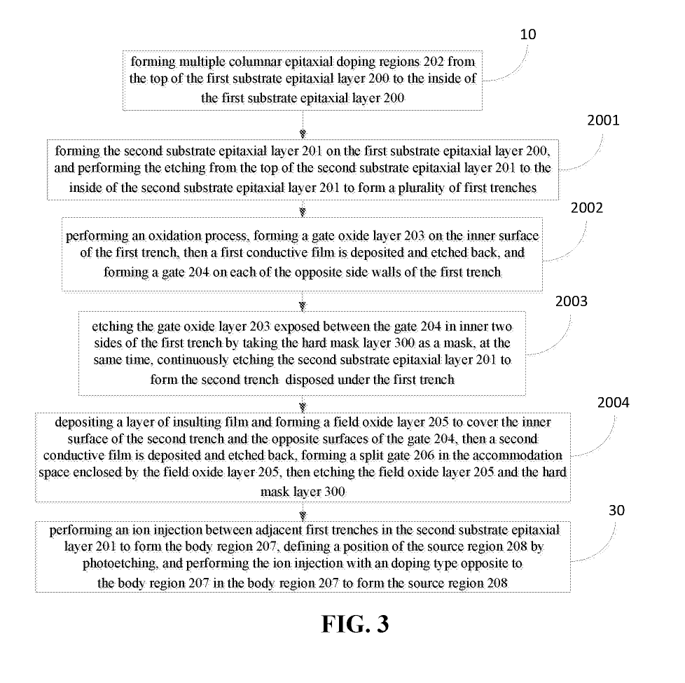

In step 20, forming a second substrate epitaxial layer 201 on the first substrate epitaxial layer 200, forming multiple trenches from the top of the second substrate epitaxial layer 201 to the inside of the second substrate epitaxial layer 201, composite gate structures are formed in the trenches. The step 20, as shown in FIG. 3, may include the steps described below.

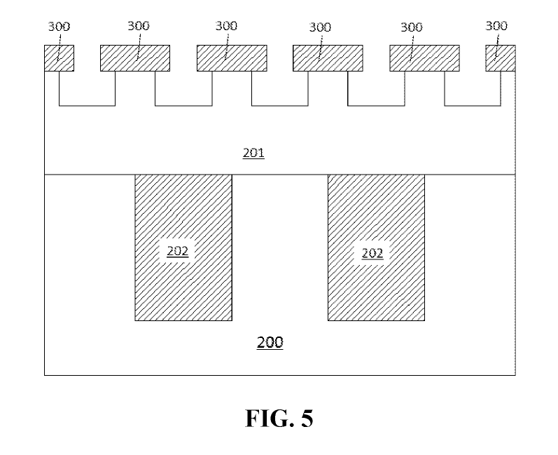

In step 2001, as shown in FIG. 5, forming the second substrate epitaxial layer 201 on the first substrate epitaxial layer 200, and the etching is performed from the top of the second substrate epitaxial layer 201 to the inside of the second substrate epitaxial layer 201 to form a plurality of first trenches.

The doping type of the second substrate epitaxial layer 201 is the first doping type and is the same as the first substrate epitaxial layer 200. Optionally, the doping concentration of the second substrate epitaxial layer 201 is greater than that of the first substrate epitaxial layer 200, so that the breakdown voltage of the super junction power transistor is increased.

In an embodiment, the processing step of forming above-mentioned first trenches includes: forming a hard mask layer 300 on the second substrate epitaxial layer 201, and etching the hard mask layer 300. An opening of the hard mask layer 300 is formed in the hard mask layer 300. Finally the etching is performed to the second substrate epitaxial layer 201 by taking the hard mask layer 300 as the mask to form the plurality of first trenches. In this embodiment, a method of combining a plasma etching and a wet etching is adopted or a method of combining a vertical plasma etching and an inclined plasma etching is adopted, and a horizontal etching is increased so that the width of the first trench is greater than a width of the opening of the hard mask layer 300.

In one embodiment, a photomask is controlled so that the number of the first trenches formed in the second substrate epitaxial layer 201 is greater than that of the columnar epitaxial doping region 202 in the first substrate epitaxial layer 200, thereby the number of subsequently formed composite gate structures can be increased, the current channels number can be increased and the on resistance of the device can be reduced.

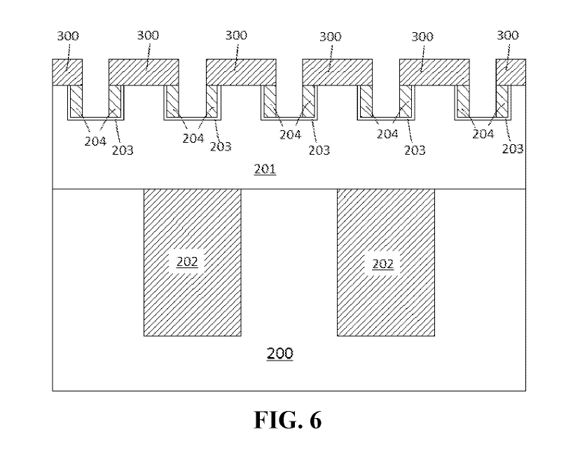

In step 2002, as shown in FIG. 6, performing an oxidation process. The gate oxide layer 203 is formed on the inner surface of the first trench, then a first conductive film is deposited and etched back, and the gate 204 is formed on each of the opposite side walls of the first trench.

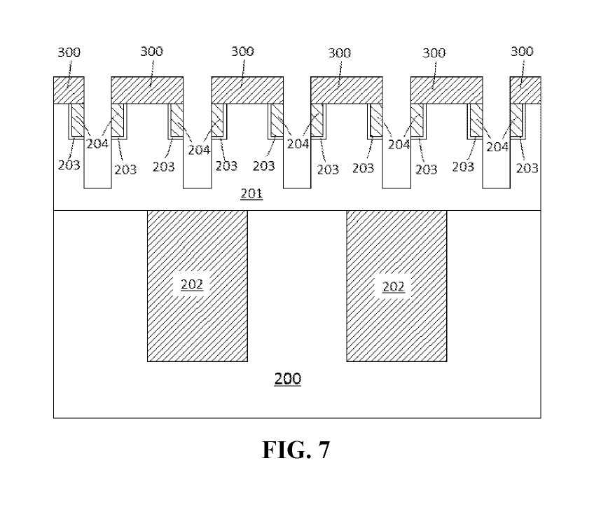

In step 2003, as shown in FIG. 7, etching the gate oxide layer 203 exposed between the gate 204 in inner two sides of the first trench by taking the hard mask layer 300 as a mask. Meanwhile, the second substrate epitaxial layer 201 is etched continuously to form the second trench which is disposed under the first trench.

In this embodiment, a width of the first trench (that is, the upper trench) is greater than that of the second trench (that is, the lower trench).

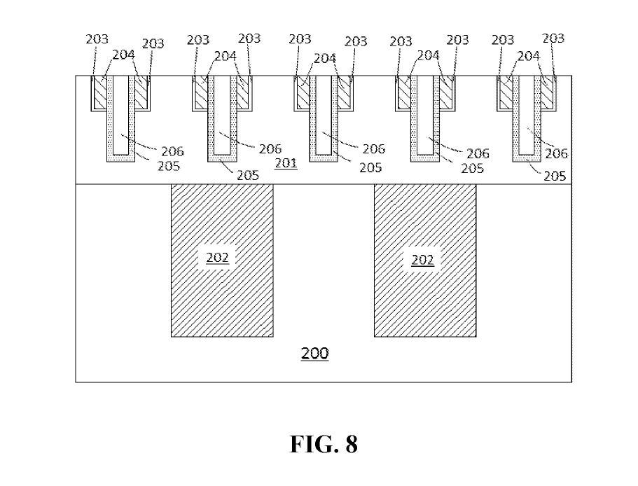

In step 2004, as shown in FIG. 8, depositing a layer of insulting film and forming the field oxide layer 205 to cover the inner surface of the second trench and the opposite surfaces of the gate 204. Then a second conductive film is deposited and etched back, the split gate 206 is formed in the accommodation space enclosed by the field oxide layer 205. Then, the field oxide layer 205 and the hard mask layer 300 are etched.

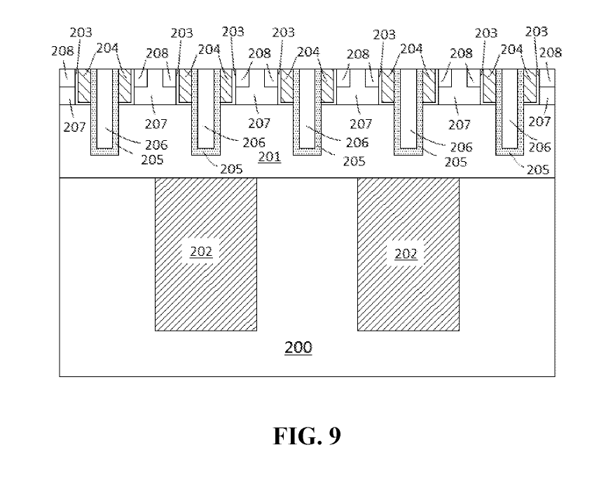

In step 30, as shown in FIG. 9, performing an ion injection between adjacent first trenches in the second substrate epitaxial layer 201 to form the body region 207, and defining a position of the source region photoetching. Then the ion injection whose doping type is opposite to the body region 207 is performed in the body region 207 to form the source region 208.

In this embodiment, the doping type of the source region 208 is the first doping type and is the same as the first substrate epitaxial layer 200 as well as the second substrate epitaxial layer 201, and the doping type of body region 207 is the second doping type. In one embodiment, the bottom of the body region 207 and the bottom of the first trench are at a same plane.

Finally, the formed structure is covered, and the insulating medium layer is deposited. A material of the insulating medium layer may be silica glass, boro-phospho-silicate glass or phosphosilicate glass. Then the position of the contact hole is defined by photoetching, and the insulating medium layer is etched to form the contact hole. The ion injection of the second doping type is performed and the metal layer is deposited to form the ohmic contact. Then the metal layer is etched to form a source electrode and a gate electrode. Meanwhile, the spilt gate 206 is connected to the gate 204 through the metal layer. Then the drain region of the first doping type is formed in the first substrate epitaxial layer 200 and the metal layer is deposited to form a drain electrode.

The super junction power transistor preparation method provided by the embodiment is adopted to manufacture the double-layer substrate epitaxial layer structure. By forming a greater number of the composite gate structures in the second substrate epitaxial layer than the columnar epitaxial doping regions in the first substrate epitaxial layer, more current channels can be formed and the on resistance of the super junction power transistor is reduced. Meanwhile, by configuring the doping concentration of the second substrate epitaxial layer to be greater than that of the first substrate epitaxial layer, the breakdown voltage of the super junction power transistor is increased. In addition, by disposing the trench structure in the second substrate epitaxial layer and self-aligned achieving the gate and the spilt gate, the overlapping area between the gate and the drain is decreased, the capacitance between the gate and the drain is reduced and the switching speed of the super junction power transistor is increased.

1. A super junction power transistor, comprising a first substrate epitaxial layer of a first doping type and a second substrate epitaxial layer of the first doping type disposed on the first substrate epitaxial layer, wherein a drain region of the first doping type and a plurality of columnar epitaxial doping regions of the second doping type are formed in the first substrate epitaxial layer, and a plurality of trenches are disposed in the second substrate epitaxial layer, wherein a composite gate structure is formed in each of the plurality of trenches, a body region of the second doping type is disposed in the second substrate epitaxial layer between adjacent trenches, and a source region of the first doping type is disposed in the body region.

2. The super junction power transistor according to claim 1, wherein the number of composite gate structures in the second substrate epitaxial layer is greater than the number of the plurality of columnar epitaxial doping regions in the first substrate epitaxial layer.

3. The super junction power transistor according to claim 2, wherein the composite gate structures are sequentially disposed on the plurality of columnar epitaxial doping regions and the first substrate epitaxial layer between adjacent columnar epitaxial doping regions.

4. The super junction power transistor according to claim 1, wherein a doping concentration of the second substrate epitaxial layer is greater than a doping concentration of the first substrate epitaxial layer.

5. The super junction power transistor according to claim 1, wherein each of the plurality of trenches comprises a first trench and a second trench with an opening disposed at the bottom of the first trench, the first trench and the second trench are disposed along a same direction, each of the composite gate structures comprises a gate, a gate oxide layer, a split gate and a field oxide layer, wherein the gate oxide layer is disposed on an inner surface of the first trench, the gate is disposed on each of opposite side walls of the first trench and the gate oxide layer is covered by the gate, the field oxide layer is disposed on opposite surfaces of the gate and an inner surface of the second trench, and the split gate is disposed in an accommodation space enclosed by the field oxide layer.

6. The super junction power transistor according to claim 5, wherein a width of the first trench is larger than a width of the second trench.

7. The super junction power transistor according to claim 5, wherein the split gate is connected to the source region through a conductive layer.

8. The super junction power transistor according to claim 1, wherein the first doping type is a P-type doping, and the second doping type is an N-type doping.

9. The super junction power transistor according to claim 1, the first doping type is N- type doping, and the second doping type is P-type doping.

10. A super junction power transistor preparation method, comprising:
forming a plurality of columnar epitaxial doping regions in a first substrate epitaxial layer;
forming a second substrate epitaxial layer on the first substrate epitaxial layer;
forming a hard mask layer on the second substrate epitaxial layer and etching the hard mask layer to form openings of the hard mask layer;
etching the second substrate epitaxial layer to form a plurality of first trenches in the second substrate epitaxial layer;
forming a gate oxide layer on an inner surface of each of the plurality of first trenches;
forming a gate on each of opposite side walls of each of the plurality of first trenches;
etching exposed gate oxide layer and etching the second substrate epitaxial layer to form a second trench;
covering an inner surface of the second trench and opposite surfaces of the gate to form a field oxide layer, and forming a spilt gate in an accommodation space enclosed by the field oxide layer;
forming a body region in the second substrate epitaxial layer, and forming a source region in the body region; and
forming a drain region at a bottom of the first substrate epitaxial layer.

11. The method according to claim 10, wherein when forming the plurality of first trenches, increasing horizontal etching so that a width of each of formed first trenches is larger than a width of a respective opening of the hard mask layer.

12. The method according to claim 10, wherein the number of the plurality of first trenches in the second substrate epitaxial layer is greater than the number of the plurality of columnar epitaxial doping regions in the first substrate epitaxial layer.

13. The method according to claim 10, wherein the second substrate epitaxial layer has a same doping type with the first substrate epitaxial layer, and a doping concentration of the second substrate epitaxial layer is greater than a doping concentration of the first substrate epitaxial layer.
